(19) United States
(12) Patent Application Publication
(10) Pub. No.: US 2026/0368402 A1
(43) Pub. Date: Nov. 19, 2026

(54) METHOD AND DEVICE FOR TRAINING SEMICONDUCTOR PROCESS VARIATION PREDICTION MODEL BASED ON DIMENSION-REDUCTION, AND NON-TRANSITORY COMPUTER READABLE MEDIUM STORING COMPUTER PROGRAM FOR PERFORMING THE METHOD

(71) Applicant: Samsung Electronics Co., Ltd., Suwon-si (KR)

(72) Inventors: Hyoung Soo KO, Suwon-si (KR); Taegeun KIM, Suwon-si (KR); Jaewon JANG, Incheon-si (KR); Donghyun YOU, Pohang-si (KR); Sangseung LEE, Incheon-si (KR); Se Jin KIM, Suwon-si (KR); Jae Myung CHOE, Suwon-si (KR); Joo Sung LEE, Suwon-si (KR)

(21) Appl. No.: 19/416,135

(22) Filed: Dec. 11, 2025

(30) Foreign Application Priority Data
May 16, 2025 (KR) 10-2025-0063891

(51) Int. Cl. G06F 30/27

(52) U.S. Cl. CPC G06F 30/27

(57) ABSTRACT

An example method for training a semiconductor process variation prediction model based on dimension-reduction may be performed by a computing device. The method may comprise inputting a plurality of parameters related to a process to a first model such that a first contour having a first dimension is output from the first model, training the first model such that a first loss function based on an error between the first contour and a first target contour having the first dimension is minimized, inputting the plurality of parameters and the first contour to a second model such that a second contour having a second dimension higher than the first dimension is output from the second model, and training the second model such that a second loss function based on an error between the second contour and a second target contour having the second dimension is minimized.

### CROSS-REFERENCE TO RELATED APPLICATION

This application claims priority from Korean Patent Application No. 10-2025-0063891 filed on May 16, 2025 in the Korean Intellectual Property Office, and all the benefits accruing therefrom under 35 U.S.C. 119, the contents of which in its entirety are herein incorporated by reference.

### BACKGROUND

Currently, most of semiconductor manufacturers perform binary iterative analysis in which computational fluid dynamics (CFD)-based reactor scale modeling (RSM) and molecular dynamics-based feature scale modeling (FSM) are combined with each other to predict flow and reaction conditions in a reactor. Such an approach may ensure high physical consistency, but takes a lot of simulation time and resources per process unit, so that the approach has a limitation in real-time prediction and multi-variable optimization in a facility design and a process optimization step.

In order to solve this problem, a high-speed prediction technique using a model based on an artificial neural network has recently attracted attention. This model has the advantage of achieving high prediction accuracy and a near-real-time prediction rate based on tens of thousands to millions of large datasets. However, in an actual semiconductor process, it is difficult to secure high-quality training data due to complex physical variables and multivariate combinations. In a data shortage situation, it is difficult to achieve reliable prediction due to problems such as overfitting. Accordingly, most of the existing studies are limited to simplified two-dimensional pattern-based prediction, and the simplified two-dimensional pattern-based prediction has a limitation in that it does not sufficiently consider dynamic and abnormal three-dimensional patterns due to rotation, natural convection, gas mixing imbalance, chamber, and showerhead structures observed on an actual wafer.

### SUMMARY

The present disclosure relates to a method of first predicting a contour in which a dimension is reduced based on a parameter related to a semiconductor process, and then training a model for predicting a final contour based on the contour in which the dimension has been reduced, and a method for enabling accurate contour prediction even in an environment in which an amount of a dataset for contour prediction is not sufficiently secured.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims and combinations thereof.

In some implementations, a method for training a semiconductor process variation prediction model based on dimension-reduction may be performed by a computing device, and the method may comprise: inputting a plurality of parameters related to a process to a first model such that a first contour having a first dimension is output from the first model; training the first model such that a first loss function based on an error between the first contour and a first target contour having the first dimension is minimized; inputting the plurality of parameters and the first contour to a second model such that a second contour having a second dimension higher than the first dimension is output from the second model; training the second model such that a second loss function based on an error between the second contour and a second target contour having the second dimension is minimized; and inputting the plurality of parameters and the first contour to the trained second model such that a third contour having the second dimension is output from the trained second model.

In some implementations, a device for training a semiconductor process variation prediction model based on dimension-reduction may comprise: a processor; and a memory storing therein instructions. When the instructions are executed by the processor, the instructions may cause the processor to: input a plurality of parameters related to a process to a first model such that a first contour having a first dimension is output from the first model; train the first model such that a first loss function based on an error between the first contour and a first target contour having the first dimension is minimized; input the plurality of parameters and the first contour to a second model such that a second contour having a second dimension higher than the first dimension is output from the second model; train the second model such that a second loss function based on an error between the second contour and a second target contour having the second dimension is minimized; and input the plurality of parameters and the first contour to the trained second model such that a third contour having the second dimension is output from the trained second model.

In some implementations, a non-transitory computer-readable medium stores therein a computer program. When the computer program is executed by a processor, the processor may be configured to: input a plurality of parameters related to a process to a first model such that a first contour having a first dimension is output from the first model; train the first model such that a first loss function based on an error between the first contour and a first target contour having the first dimension is minimized; input the plurality of parameters and the first contour to a second model such that a second contour having a second dimension higher than the first dimension is output from the second model; train the second model such that a second loss function based on an error between the second contour and a second target contour having the second dimension is minimized; and input the plurality of parameters and the first contour to the trained second model such that a third contour having the second dimension is output from the trained second model.

The specific details of other implementations are included in the detailed description and drawings.

### BRIEF DESCRIPTION OF THE DRAWINGS

The above and other aspects and features of the present disclosure will become more apparent by describing in detail implementations thereof with reference to the attached drawings.

FIG. 1 is a flowchart illustrating an example of a method for training a semiconductor process variation prediction model.

FIG. 2 is an example of a flowchart illustrating a step of outputting a first contour and a step of training a first model of FIG. 1.

FIG. 3 illustrates an example of a basis function.

FIG. 4 conceptually illustrates an example of a semiconductor process variation prediction method.

FIG. 5 is a flowchart illustrating an example of a method for training a semiconductor process variation prediction model.

FIG. 6 shows an example of a comparison between a semiconductor process variation prediction method with dimension-reduction and a semiconductor process variation prediction method without dimension-reduction.

FIG. 7 is an example of a graph illustrating an accuracy of a semiconductor process variation prediction model.

FIG. 8 is an example of a graph illustrating a loss based on the number of times of training a semiconductor process variation prediction model.

FIG. 9 is a block diagram illustrating an example configuration of a device for training a semiconductor process variation prediction model.

### DETAILED DESCRIPTIONS

Hereinafter, some implementations of the present disclosure will be described in detail with reference to the attached drawings. Advantages and features of the present disclosure, and a method of achieving the advantages and features will become apparent with reference to implementations described later in detail together with the accompanying drawings. However, implementations of the present disclosure are not limited to the implementations as disclosed below, but may be implemented in various different forms. Thus, these implementations are set forth only to make the present disclosure complete, and to completely inform the scope of the present disclosure to those of ordinary skill in the technical field to which the present disclosure belongs, and the present disclosure is only defined by the scope of the claims.

The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure gist of the present disclosure. Examples of various implementations are illustrated and described further below. It will be understood that the description herein is not intended to limit the claims to the specific implementations described. On the contrary, it is intended to cover alternatives, modifications, and equivalents as may be included within the spirit and scope of the present disclosure as defined by the appended claims.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. The terminology used herein is directed to the purpose of describing particular implementations only and is not intended to be limiting of the present disclosure. As used herein, the singular constitutes “a” and “an” are intended to include the plural constitutes as well, unless the context clearly indicates otherwise.

Additionally, in describing the components of the present disclosure, terms such as first, second, A, B, a, and b may be used. These terms are only used to distinguish one component from another component, and the nature, sequence, order, or number of the component are not limited by the term. It should be understood that when a component is described as being “connected,” “coupled,” or “combined” to another component, the component may be directly connected, coupled, or combined to another component, still another component may be “interposed” therebetween, and thus the component may be connected, coupled, or combined to another component via the still another component.

It will be further understood that the terms “comprise”, “comprising”, “include”, and “including” as used herein specify the presence of the stated features, steps, operations, elements, and/or components, but do not preclude the presence or addition of one or more other features, steps, operations, elements, components, and/or portions thereof.

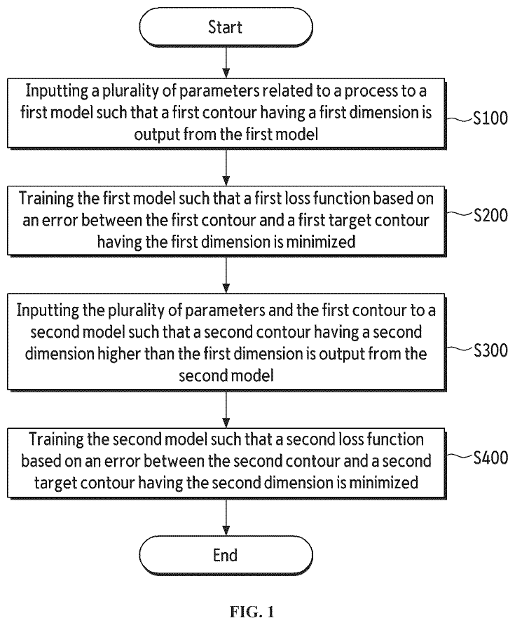

FIG. 1 is a flowchart illustrating an example of a method for training a semiconductor process variation prediction model.

Predicting a semiconductor process variation is to predict a contour that spatially visualizes various parameters (e.g., a thickness, a doping concentration, temperature distribution, electrical properties, etc.) related to the process. The contour may be used to evaluate distribution non-uniformity on the wafer. In this regard, the prediction of the contour may be performed by an image prediction model (e.g., implemented as a convolutional neural network (CNN), a generative adversarial neural network (GAN), or the like) that receives the parameters related to the process.

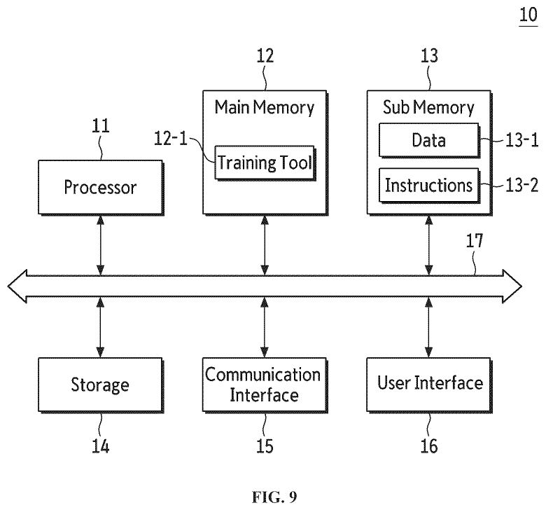

In particular, according to an implementation of the present disclosure, an image prediction model for contour prediction and a model for dimension-reduction are combined with each other. Thus, the contour may not be predicted directly from the parameter related to a process. Rather, a low-dimensional contour may be predicted first and then a high-dimensional final contour may be predicted. That is, the semiconductor process variation prediction model according to an implementation of the present disclosure represents a combined model in which the model for dimension-reduction and the image prediction model are combined with each other. Tool for training this combined model may be a program including a plurality of instructions (e.g., 13-2 of FIG. 9) performed by a processor (e.g., 11 of FIG. 9). Accordingly, the method for training the semiconductor process variation prediction model may be referred to as a computer implemented method for training the semiconductor process variation prediction model.

For reference, FIGS. 1 to 2 and 5, which will be described later, illustrate steps/operations of a method performed in a training device 10 for training the semiconductor process variation prediction model of FIG. 9. Accordingly, in the following descriptions, it may be understood that when a subject which performs a specific step/operation is omitted, the subject is the training device 10 for training the semiconductor process variation prediction model of FIG. 9.

Referring to FIG. 1, in operation S100, a plurality of parameters related to a process may be input to a first model, and a first contour having a first dimension may be output therefrom. In this regard, the plurality of parameters related to the process may include at least one of a temperature, a pressure, a flow rate, a humidity, pH, power, voltage, current, etc. In addition, in some implementations, the plurality of parameters related to the process may further include values of a process recipe as preset condition values for the equipment for the process. In operation S200, a first loss function may be calculated based on an error between the first contour and a first target contour having the first dimension, and a first model may be trained such that the first loss function is minimized.

The first contour output in operation S100 is a contour having a lower dimension than that of a finally predicted contour (a second contour to be described later). The first model is a model for reducing the above-described dimension. The first model may be configured to receive the plurality of parameters related to the process, extract a plurality of coefficients respectively corresponding to a plurality of predetermined basis functions, and output the first contour of a low dimension based on the plurality of coefficients and the plurality of basis functions. In this regard, each of the plurality of basis functions may be a Zernike basis function. In this case, the first model may be a Zernike-based model.

The plurality of basis functions may be orthogonal to each other, and the first dimension may correspond to the number of the plurality of basis functions. In this regard, training the first model means training the first model to extract the coefficient such that the first loss function is minimized.

In operation S300, the plurality of parameters and the first contour may be input to a second model, and a second contour having a second dimension higher than the first dimension may be output therefrom. That is, the second dimension may correspond to the dimension of the contour to be finally predicted. The second model corresponds to the above-described image prediction model and may be implemented as at least one of a convolutional neural network (CNN) or a generative adversarial neural network (GAN). However, the present disclosure is not limited thereto. In operation S400, a second loss function based on an error between the second contour and a second target contour having the second dimension may be calculated, and the second model may be trained such that a second loss function is minimized. For example, training the second model may include adjusting the number of layers or hyperparameters of the second model.

In one example, each of the first loss function and the second loss function may be calculated using a mean squared error (MSE) between the corresponding contour and the target contour. Each of the first and second loss functions may be minimized using a gradient descent method. That is, the training of each of the models according to an implementation of the disclosure may be performed so as to minimize each of the first loss function and the second loss function corresponding to each of the first model and the second model.

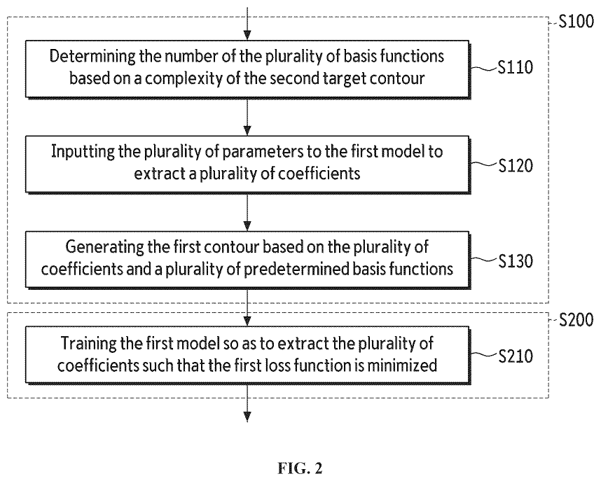

Hereinafter, the operations S100 to S200 will be described in more detail with reference to FIG. 2.

FIG. 2 is an example of a flowchart illustrating in detail the operation S100 of outputting the first contour and the operation S200 of training the first model of FIG. 1. Referring to FIG. 2, in operation S110, the number of a plurality of basis functions may be determined based on a complexity of the second target contour. As described above, the number of basis functions may determine the dimension of the first contour. As the number of basis functions increases, an amount of computation required to output the first contour may increase. Accordingly, the dimension (i.e., the number of the plurality of basis functions) of the first contour may be flexibly determined based on the complexity of the contour to be finally predicted.

In operation S120, the plurality of parameters may be input to the first model, and a plurality of coefficients may be extracted therefrom. In this regard, the plurality of coefficients are coefficients respectively correspond to the plurality of basis functions, and the number of the plurality of coefficients and the number of the plurality of basis functions may be equal to each other. In operation S130, the first contour may be generated based on the plurality of coefficients and the plurality of basis functions. In operation S210, the first model may be trained to extract the plurality of coefficients such that the first loss function is minimized.

In the implementation of FIG. 2, the plurality of basis functions may be Zernike basis functions. In addition, a component of each of the plurality of basis functions may be determined based on a shape of the facility for performing the semiconductor process.

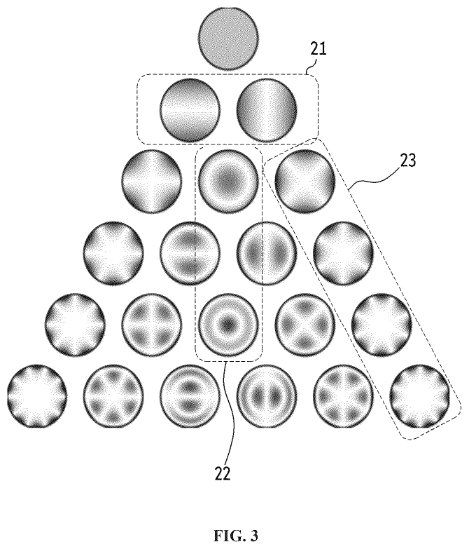

FIG. 3 illustrates an example of a basis function. Referring to FIG. 3, the Zernike basis function is shown. The Zernike basis function is an orthogonal polynomial defined on a unit disk (a circular area having a radius of 1). The basis functions are orthogonal to each other. Thus, the contour may be expressed based on a linear combination of the basis functions. In particular, the Zernike basis function may be used to quantify the complexity of the system with a circular symmetrical structure. The case of FIG. 3 is based on a fifth-order Zernike polynomial, which may include 21 Zernike basis functions and may correspond to 21 dimensions in a vector space. That is, when the order of the Zernike polynomial is n, a total number of basis functions (i.e., the number of dimensions in the vector space) may be calculated as (n+1)(n+2)/2.

The Zernike basis function may be divided into three components, i.e., radial, tilt, and theta, depending on a form. The radial component 21 represents a change in a value as a position displaces from a center of a circle to an edge thereof. The tilt component 22 represents a shape in which an entire surface is tilted to one side. Finally, the theta component 23 represents an asymmetric shape in which a value varies according to a direction in which a position rotates around a center of a circle.

Each basis function may have a physical correlation with the shape of the facility for a semiconductor process. For example, in the facility, the influence caused by the shower head (e.g., non-uniform film thickness from the center of the wafer to the edge thereof) may have a physical correlation with the radial component 21 of the base function, the influence caused by the gas inlet (e.g., asymmetry caused by the inflow of gas only in a specific direction) may have a physical correlation with the tilt component 22 and the theta component 23, and the influence caused by the pump duct (e.g., reduction of the film thickness or the plasma density in an area from which the gas escapes) may have a physical correlation with the radial component 21 and the tilt component 22.

Assuming that a grid size of the contour to be finally predicted is 100×100 and the number of data points is 10000, the Zernike basis function, the coefficient, and the target contour (a ground truth) may be expressed based on a following Equation 1:

$$[ \begin{matrix}{Z}_{1} ( 1 ) & {Z}_{1} ( 2 ) & … & {Z}_{1} ( 10000 ) \\ {Z}_{2} ( 1 ) & {Z}_{2} ( 2 ) & … & {Z}_{2} ( 10000 ) \\ ⋮ & ⋮ & ⋱ & ⋮ \\ {Z}_{21} ( 1 ) & {Z}_{21} ( 2 ) & … & {Z}_{21} ( 10000 )\end{matrix} ] [ \begin{matrix}{c}_{1} \\ {c}_{2} \\ ⋮ \\ {c}_{21}\end{matrix} ] = [ \begin{matrix}{f}_{1} \\ {f}_{2} \\ ⋮ \\ {f}_{10000}\end{matrix} ] . \qquad [ Equation 1$$

where each of Z₁, . . . , Z₂₁ represents the basis function, each of c₁, . . . , c₂₁ represents the coefficient, and each of f₁, . . . , f₁₀₀₀₀ represent a data value of the target contour (i.e., the ground truth). In this regard, the coefficients c₁, . . . , c₂₁ may be extracted using a least squares method. After the coefficients have been extracted, a low-dimensional contour (i.e., the first contour as described with reference to FIGS. 1 to 2) may be generated via between a product between each basis function and the coefficient.

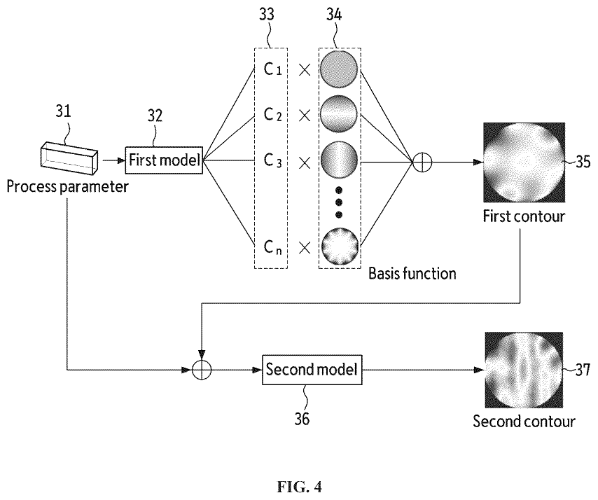

FIG. 4 conceptually illustrates an example of a semiconductor process variation prediction method. Referring to FIG. 4, a process parameter 31 may be input to the first model 32, and a coefficient 33 may be extracted therefrom. A first contour 35 of a low dimension may be generated via the operation between the extracted coefficient 33 and a basis function 34. Then, the generated first contour 35 and the process parameter 31 may be input to a second model 36 again, and finally, a high-dimensional second contour 37 may be generated.

In this process, the first model 32 and the second model 36 may be trained, respectively. The first model 32 may be trained such that the coefficient 33 is extracted such that the first loss function based on an error between the first contour 35 and the first target contour (i.e., the ground truth of the low-dimensional contour) having the same dimension is minimized. The second model 36 may be trained such that the second contour 37 is generated such that the second loss function based on an error between the second contour 37 and the second target contour (i.e., the ground truth of the final contour) having the same dimension is minimized.

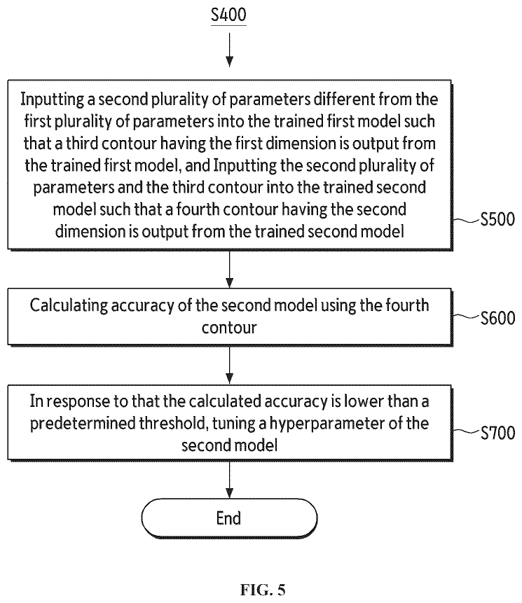

FIG. 5 is a flowchart illustrating an example of a method for training a semiconductor process variation prediction model. Referring to FIG. 5, after operation S400, in operation S500, a second plurality of parameters different from the plurality of parameters input in the operations S100 and S300 may be input to the trained first model to output a third contour having the first dimension. The second plurality of parameters and the third contour may be input to the trained second model to output a fourth contour having the second dimension. That is, the plurality of parameters input in the operations S100 and S300 may correspond to a training dataset, the second plurality of parameters input in the operation S500 may correspond to a test dataset, and the third contour and the fourth contour may respectively correspond to respective output results of the first model and the second model using the test dataset.

In operation S600, the accuracy of the second model may be calculated using the fourth contour, and in operation S700, in response to that the calculated accuracy is lower than a predetermined threshold, a hyperparameter of the second model may be further adjusted. That is, the operation S700 may correspond to a fine-tuning process of the second model. Although only the fine tuning process of the second model is described in the operations S600 to S700, the present disclosure is not limited thereto, and in some implementations, the fine tuning of the first model using the third contour may also be performed.

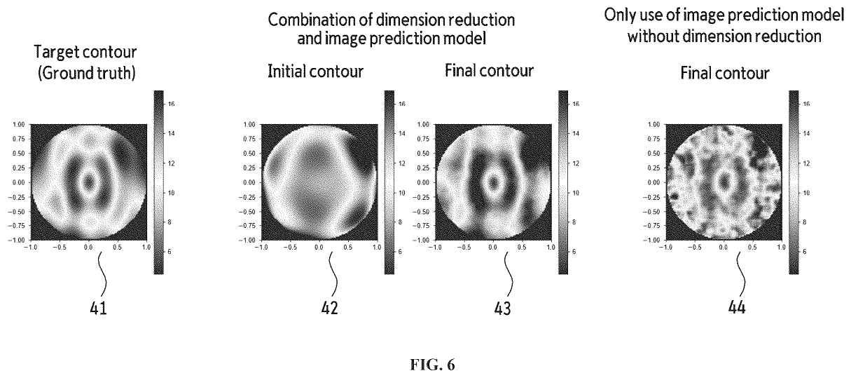

FIG. 6 shows an example of a comparison between a semiconductor process variation prediction method with dimension-reduction and a semiconductor process variation prediction method without dimension-reduction. Referring to FIG. 6, a contour 41 corresponds to the final target contour, a contour 42 corresponds to the low-dimensional contour output through the first model (a dimension-reduced model), a contour 43 corresponds to the high-dimensional final contour output through the second model (an image prediction model) based on the contour 42, and a contour 44 corresponds to a final contour output using only the second model without the first model. Assuming that a layer configuration and the hyperparameter of the second model are constant, in the contour 44 obtained in a manner in which the dimension-reduction is not used, deterioration in the predictive power such as noise occurs compared with the contour 41. However, according to an implementation of the present disclosure, in the contour 43 obtained in a manner in which the dimension-reduction is used, the noise is suppressed and the predictive power is improved compared to the contour 44.

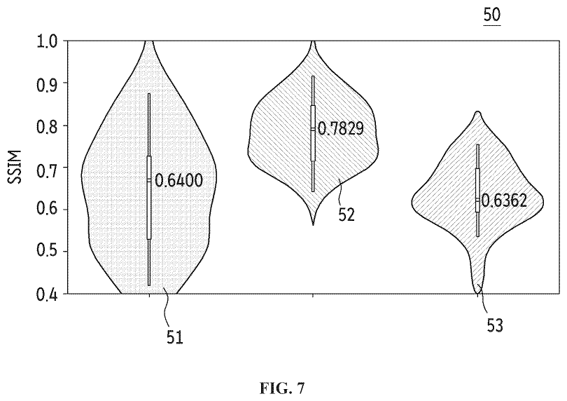

FIG. 7 is an example of a graph 50 illustrating the accuracy of a semiconductor process variation prediction model. Referring to FIG. 7, a structural similarity index (SSIM) is shown as an indicator of the accuracy. SSIM is an index indicating a similarity between brightness, contrasts, or structures of two images in a range of 0 and 1. As the SSIM value is closer to 1, the two images are more similar to each other. As the SSIM value is closer to 0, the images are more different from each other. In the graph 50, a reference numeral 51 denotes the SSIM between the first contour as an output of the first model (dimension-reduced model) and the target contour. A reference numeral 52 denotes a SSIM between the second contour as an output of the second model (image prediction model) based on the first contour and the target contour. A reference numeral 53 denotes a SSIM between a contour predicted using only the second model without using the low-dimensional contour and the target contour. Based on a comparison result between the reference numeral 52 and the reference numeral 53, the predictive power of the contour has increased from 0.6362 to 0.7829 by about 23% according to an implementation of the present disclosure.

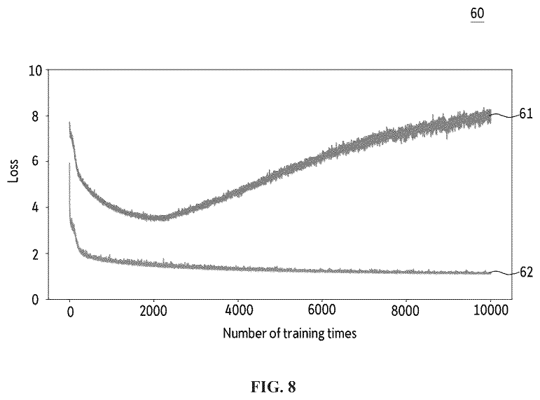

FIG. 8 is an example of a graph 60 illustrating a loss based on the number of times of training a semiconductor process variation prediction model. Referring to FIG. 8, a reference numeral 61 denotes a loss based on the number of times of training the second model when only the second model is trained without using the low-dimensional contour. A reference numeral 62 denotes a loss based on the number of times of training the second model when the low-dimensional contour is used according to an implementation of the present disclosure. That is, referring to FIG. 8, it may be identified that learning stability has been secured according to an implementation of the present disclosure.

FIG. 9 is a block diagram illustrating an example configuration of a device 10 for training a semiconductor process variation prediction model. Hereinafter, for convenience of description, the device 10 for training the semiconductor process variation prediction model will be referred to as a training device 10.

In detail, FIG. 9 is a block diagram of the training device 10 performing the method for training the semiconductor process variation prediction model described above. Hereinafter, descriptions will be given with reference to FIGS. 2 to 8, and the same reference numerals refer to the same components, and redundant descriptions will be omitted.

Referring to FIG. 9, the training device 10 may include a processor 11, a main memory 12, a sub-memory 13, a storage 14, a communication interface 15, a user interface 16, and a bus 17. The training device 10 may be a part of a semiconductor design system. The semiconductor design system may include various design and verification simulation programs. The training device 10 may be implemented as a general-purpose computer or a special-purpose computer for semiconductor simulation.

The processor 11 may control the training device 10 and train the semiconductor process variation prediction model. The processor 11 may execute software executed in the training device 10. The software may include an application program, an operating system, a device driver, etc. The processor 11 may execute the operating system stored in the main memory 12. The processor 11 may execute various application programs executed based on the operating system. For example, the processor 11 may execute tool for training the semiconductor process variation prediction model by executing the instructions 13-2 stored in the sub-memory 13. For example, the processor 11 may execute training tool 12-1 stored in the main memory 12. Accordingly, the processor 11 may perform a series of operations as illustrated in FIGS. 1, 2, and 5. For example, the processor 11 may train the semiconductor process variation prediction model using data 13-1 stored in the sub-memory 13 as the training dataset.

The main memory 12 may be a working memory of the processor 11. The main memory 12 may store therein the application program, the operating system, the device driver, etc. executed in the processor 11. For example, the main memory 12 may store therein the training tool 12-1. The training tool 12-1 may be an application program for training the semiconductor process variation prediction model. The training tool 12-1 may be executed through the processor 11.

The main memory 12 may temporarily store therein the data 13-1 or the instructions 13-2 required by the processor 11 among the data 13-1 and the instructions 13-2 stored in the sub-memory 13. The main memory 12 may include at least one of a volatile memory or a nonvolatile memory. For example, the main memory 12 may include at least one of a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), a dynamic RAM (DRAM), a static RAM (SRAM), and a synchronous DRAM (SDRAM).

The sub-memory 13 may be a secondary memory of the training device 10. The sub-memory 13 may store therein the data 13-1 and the instructions 13-2. For example, the sub-memory 13 may store therein the training dataset and the test dataset including the plurality of parameters related to the semiconductor process, and the low-dimensional target contour and the high-dimensional target contour. The training dataset and the test dataset including the plurality of parameters and the target contours may be transmitted to the sub-memory 13 through the communication interface 15 or the storage 14 in the form of the data 13-1.

For example, the instructions 13-2 may include instructions for inputting a plurality of parameters related to a process to a first model such that a first contour having a first dimension is output from the first model; training the first model such that a first loss function based on an error between the first contour and a first target contour having the first dimension is minimized; inputting the plurality of parameters and the first contour to a second model such that a second contour having a second dimension higher than the first dimension is output from the second model; and training the second model such that a second loss function based on an error between the second contour and a second target contour having the second dimension is minimized.

The sub-memory 13 may include a memory card (MMC, eMMC, SD, MicroSD, etc.), a hard disk drive (HDD), a solid state drive (SSD), an optical disk drive (ODD), and the like. The sub-memory 13 may include a NAND-type flash memory. However, the present disclosure is not limited thereto, and the sub-memory 13 may include a next-generation nonvolatile memory such as PRAM, MRAM, ReRAM, FRAM, or the like, or a NOR flash memory.

The storage 14 may include a removable portable storage. For example, the data 13-1 and the instructions 13-2 stored in the sub-memory 13 may be transferred from the storage 14 to the sub-memory 13. The storage 14 may be based on one of various standards such as a universal serial bus (USB), a serial advanced technology attachment (SATA), etc.

The communication interface 15 may communicate with an external device in a wired or wireless manner. For example, the data 13-1 and the instructions 13-2 may be stored in the sub-memory 13 from the external device through the communication interface 15. The data 13-1 and the instructions 13-2 stored in the sub-memory 13 may be transmitted to the external device through the communication interface 15. The communication interface 15 may be based on Ethernet.

The user interface 16 may receive an execution command of the training tool 12-1 from a user. The user interface 16 may include various user input interface devices such as a touch sensor, keyboard, mouse, pointing device, etc. The user interface 16 may transmit a training result (e.g., a training result as illustrated in FIGS. 6 to 8) of the semiconductor process variation prediction model according to an implementation of the disclosure to the user. The user interface 16 may include various user output interface devices such as a monitor, a printer, etc. The user interface 16 may display a result of training the semiconductor process variation prediction model, and the contour finally predicted via the trained prediction model through the user output interface device.

The bus 17 may provide a network inside the training device 10. The processor 11, the main memory 12, the sub-memory 13, the storage 14, the communication interface 15, and the user interface 16 may be electrically connected to each other via the bus 17 and may exchange data with each other.

According to an implementation of the present disclosure, the dimension-reduced model operating even in a small number of datasets and the image prediction model effective for non-linear pattern prediction may be combined with each other, thereby predicting the contour related to the process with higher accuracy than that when only the image prediction model is used, even with a small number of datasets.

Various implementations of the present disclosure and the effects according to those implementations have been mentioned above with reference to FIGS. 1 to 9. The effects according to the technical idea of the present disclosure are not limited to the effects as mentioned above, and other effects not mentioned may be clearly understood by those skilled in the art from the above descriptions.

All the components that constitute the implementation of the present disclosure are described as being combined with each other or operating in combination with each other. However, the present disclosure is not necessarily limited to this implementation. In other words, within the scope of the purpose of the present disclosure, all of the components may operate in a selective combination manner of at least two thereof with each other.

Although the operations are shown as being executed in a specific order in the drawings, it should not be understood that the operations should be performed in the specific order as shown or in a sequential order or that all illustrated operations should be performed to obtain the desired result.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations of the present disclosure have been described with reference to the accompanying drawings, implementations of the present disclosure are not limited to the above implementations, but may be implemented in various different forms. A person skilled in the art may appreciate that the present disclosure may be practiced in other concrete forms without changing the technical spirit or essential characteristics of the present disclosure. Therefore, it should be appreciated that the implementations as described above is not restrictive but illustrative in all respects.

What is claimed is:

1. A method for training a semiconductor process variation prediction model based on dimension-reduction, the method being performed by a computing device, the method comprising:
inputting a plurality of parameters related to a process to a first model such that a first contour having a first dimension is output from the first model;
training the first model such that a first loss function based on an error between the first contour and a first target contour having the first dimension is minimized;
inputting the plurality of parameters and the first contour to a second model such that a second contour having a second dimension is output from the second model, the second dimension being higher than the first dimension;
training the second model such that a second loss function based on an error between the second contour and a second target contour having the second dimension is minimized; and
inputting the plurality of parameters and the first contour to the trained second model such that a third contour having the second dimension is output from the trained second model.

2. The method of claim 1, wherein inputting the plurality of parameters to the first model such that the first contour is output from the first model includes:
inputting the plurality of parameters to the first model to extract a plurality of coefficients; and
generating, based on the plurality of coefficients and a plurality of predetermined basis functions, the first contour, wherein a number of the plurality of coefficients and a number of the plurality of basis functions are equal; and
wherein training the first model includes training the first model to extract the plurality of coefficients such that the first loss function is minimized.

3. The method of claim 2, wherein each basis function of the plurality of basis functions is a Zernike basis function.

4. The method of claim 3, wherein a component of each basis function of the plurality of basis functions is determined based on a shape of a facility for performing the process.

5. The method of claim 2, wherein inputting the plurality of parameters to the first model such that the first contour is output from the first model includes determining the number of the plurality of basis functions based on a complexity of the second target contour.

6. The method of claim 1, wherein the second model is implemented as at least one of a convolutional neural network (CNN) or a generative adversarial neural network (GAN).

7. The method of claim 1, wherein the plurality of parameters are a first plurality of parameters, and wherein the method comprises:
inputting a second plurality of parameters into the trained first model such that a third contour having the first dimension is output from the trained first model, the second plurality of parameters being different from the first plurality of parameters;
inputting the second plurality of parameters and the third contour into the trained second model such that a fourth contour having the second dimension is output from the trained second model;
calculating accuracy of the second model using the fourth contour; and
tuning, based on the calculated accuracy being lower than a predetermined threshold, a hyperparameter of the second model.

8. A device for training a semiconductor process variation prediction model based on dimension-reduction, the device comprising:
a processor; and
a memory storing instructions that, when executed by the processor, are operable to cause the processor to perform operations comprising:
inputting a plurality of parameters, related to a process, to a first model such that a first contour having a first dimension is output from the first model;
training the first model such that a first loss function based on an error between the first contour and a first target contour having the first dimension is minimized;
inputting the plurality of parameters and the first contour to a second model such that a second contour having a second dimension is output from the second model, the second dimension being higher than the first dimension;
training the second model such that a second loss function based on an error between the second contour and a second target contour having the second dimension is minimized; and
inputting the plurality of parameters and the first contour to the trained second model such that a third contour having the second dimension is output from the trained second model.

9. The device of claim 8, wherein inputting the plurality of parameters to the first model such that the first contour is output from the first model includes:
inputting the plurality of parameters to the first model to extract a plurality of coefficients; and
generating, based on the plurality of coefficients and a plurality of predetermined basis functions, the first contour, wherein a number of the plurality of coefficients and a number of the plurality of basis functions are equal; and
wherein training the first model includes training the first model to extract the plurality of coefficients such that the first loss function is minimized.

10. The device of claim 9, wherein each basis function of the plurality of basis functions is a Zernike basis function.

11. The device of claim 10, wherein a component of each basis function of the plurality of basis functions is determined based on a shape of a facility for performing the process.

12. The device of claim 9, wherein inputting the plurality of parameters to the first model such that the first contour is output from the first model includes determining the number of the plurality of basis functions based on a complexity of the second target contour.

13. The device of claim 8, wherein the second model is implemented as at least one of a convolutional neural network (CNN) or a generative adversarial neural network (GAN).

14. The device of claim 8, wherein the plurality of parameters are a first plurality of parameters, and wherein the operations comprise:
inputting a second plurality of parameters into the trained first model such that a third contour having the first dimension is output from the trained first model, the second plurality of parameters being different from the first plurality of parameters;
inputting the second plurality of parameters and the third contour into the trained second model such that a fourth contour having the second dimension is output from the trained second model;
calculating accuracy of the second model using the fourth contour; and
tuning, based on the calculated accuracy being lower than a predetermined threshold, a hyperparameter of the second model.

15. A non-transitory computer-readable medium storing a computer program, that, when executed by one or more processors, causes the one or more processors to perform operations comprising:
inputting a plurality of parameters related to a process to a first model such that a first contour having a first dimension is output from the first model;
training the first model such that a first loss function based on an error between the first contour and a first target contour having the first dimension is minimized;
inputting the plurality of parameters and the first contour to a second model such that a second contour having a second dimension is output from the second model, the second dimension being higher than the first dimension;
training the second model such that a second loss function based on an error between the second contour and a second target contour having the second dimension is minimized; and
inputting the plurality of parameters and the first contour to the trained second model such that a third contour having the second dimension is output from the trained second model.

16. The non-transitory computer-readable medium of claim 15, wherein inputting the plurality of parameters to the first model such that the first contour is output from the first model includes:
inputting the plurality of parameters to the first model to extract a plurality of coefficients; and
generating, based on the plurality of coefficients and a plurality of predetermined basis functions, the first contour, wherein a number of the plurality of coefficients and a number of the plurality of basis functions are equal; and
wherein training the first model includes training the first model to extract the plurality of coefficients such that the first loss function is minimized.

17. The non-transitory computer-readable medium of claim 16, wherein each basis function of the plurality of basis functions is a Zernike basis function.

18. The non-transitory computer-readable medium of claim 16, wherein inputting the plurality of parameters to the first model such that the first contour is output from the first model includes determining the number of the plurality of basis functions based on a complexity of the second target contour.

19. The non-transitory computer-readable medium of claim 15, wherein the second model is implemented as at least one of a convolutional neural network (CNN) or a generative adversarial neural network (GAN).

20. The non-transitory computer-readable medium of claim 15, wherein the plurality of parameters are a first plurality of parameters, and wherein the operations comprise:
inputting a second plurality of parameters into the trained first model such that a third contour having the first dimension is output from the trained first model, the second plurality of parameters being different from the first plurality of parameters;
inputting the second plurality of parameters and the third contour into the trained second model such that a fourth contour having the second dimension is output from the trained second model;
calculating accuracy of the second model using the fourth contour; and
tuning, based on the calculated accuracy is lower than a predetermined threshold, a hyperparameter of the second model.
